(19) United States
(12) Patent Application Publication
(10) Pub. No.: US 2008/0310939 A1
(43) Pub. Date: Dec. 18, 2008

(54) SYSTEM AND METHOD FOR USE IN A LITHOGRAPHY TOOL

(75) Inventors: Chieh-Huan Ku, Sijhih City (TW); Yung-Ho Chen, Hsin-Chu (TW); Jyh-Chang Lin, Sanchong City (TW); Richard Peng, Hsinchu County (TW)

Correspondence Address: HAYNES AND BOONE, LLP, 901 Main Street, Suite 3100, Dallas, TX, 75202, US

(73) Assignee: TAIWAN SEMICONDUCTOR MANUFACTURING COMPANY, LTD., Hsin-Chu (TW)

(21) Appl. No.: 11/763,597

(22) Filed: Jun. 15, 2007

(51) Int. Cl. H01L 21/31

(52) U.S. Cl. 414/222.02; 414/935

(57) ABSTRACT

A system for use in semiconductor manufacture including a process tool for processing wafers; a buffer coupled to the process tool for holding wafer waiting to be processed by the process tool; an input load port coupled to the buffer for feeding in wafers ready for processing from a load-in container; an output load port coupled to the process tool for feeding out wafers that have been processed by the process tool to a load-out container; and a track module for transporting the wafers between the buffer, the process tool, and the input and output load ports.

### BACKGROUND

This invention relates generally to semiconductor device manufacturing and more specifically to system and method for implementing a load port buffer design in a lithography tool.

The mass production of semiconductor devices utilizes different equipment for different processes. For example, photolithography is a complex process that produces circuit patterns on a surface of a wafer using light-sensitive photoresist material and controlled exposure of light radiation. To accomplish this, a lot of wafers may be automatically transported to and from various locations to perform the different processes that are required. Typically, the lot of wafers may housed in a closed container such as a front opening unified pod (FOUP) and transported by an overhead transport service. At one such location, the FOUP may be placed in a load port that interfaces with a lithography tool where an exposure process may be performed on the wafer. However, as lithography tools advance and wafer throughput increases there may be times during processing when wafers may not be available for the lithography tool due to a load port shortage and/or waiting time of the overhead transport service.

Therefore, what is needed is a simple and cost-effective system and method to supply wafers so as to minimize idle or waiting time of the lithography tool.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic diagram of a load port design for use with a lithography tool according to one embodiment of the present disclosure.

FIG. 2 is a schematic diagram of a buffer that may be utilized with the load port design of FIG. 1.

FIGS. 3A and 3B are schematic diagrams of a conventional load port design and a shuttle bus design that may be utilized with the load port design of FIG. 1.

FIG. 4 is a flow chart for a method of supplying wafers to a lithography tool utilizing the load port design of FIG. 1.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

In semiconductor manufacturing, integrated circuit devices are produced by a plurality of processes in a wafer fabrication facility (referred to as a fab). These processes, and associated processing tools, may include thermal oxidation, fusion, ion implantation, rapid thermal processing (RTP), chemical vapor deposition (CVD), physical vapor deposition (PVD), epitaxy, etch, and photolithography. The integrated circuit devices are typically fabricated by processing one or more wafers as a “lot” (also referred to as a batch) with a series of processing tools at various stations. The lot of wafers may be housed in a container and transported to the various stations by an automated handling system which includes an overhead transport (OHT) service. The lot of wafers includes an identification number (ID) that is used for tracking and recording the lot as it travels throughout the fab. Additionally, the lot ID may provide information regarding what processes and/or recipes may be performed when the lot arrives at the various stations for processing.

In a 300 mm (12 inch) wafer fab, a lot of wafers may be transported in a closed container such as a Front Opening Unified Pod (FOUP) to the various stations where the processing tools are located. At a particular station, the FOUP may be placed in a load port that interfaces with the processing tool. The load port is configured to open and close a lid of the FOUP so that the lot of wafers may be transferred to and from the processing tool via a robot and track module. After processing the lot of wafers, the FOUP may be transported by the OHT service to a next station for further processing. The FOUP and load port may be configured in accordance with standards by SEMI (Semiconductor Equipment and Materials International).

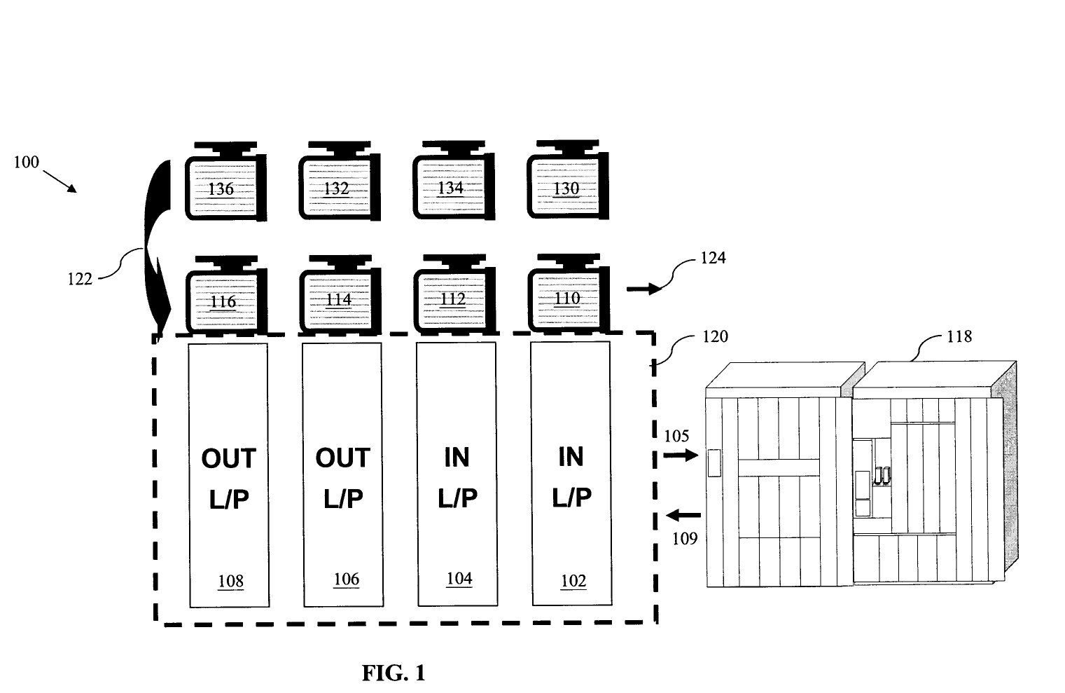

Referring to FIG. 1, illustrated is a schematic diagram of a load port design 100 for supplying wafers to a processing tool according to one embodiment of the present disclosure. The load port design 100 may comprise a first and second input load port 102, 104 (IN L/P) configured for only feeding in 105 wafers to a process tool for processing. The load port design 100 may further comprises a first and second output load port 106, 108 (OUT L/P) configured for only feeding out 109 processed wafers from the process tool. The input and output load ports 102, 104, 106, 108 may also be configured to receive containers such as a plurality of FOUP 110, 112, 114, 116 which will be explained in greater detail below.

The process tool may include a lithography tool 118 for patterning a surface of the wafer by an exposure process with controlled light radiation. The lithography tool 118 may include various types such as steppers, scanners, step-and-scan tools, or other suitable tools. Additionally, the lithography tool may also include immersion lithography tools. The load port design 100 may further comprises a track-in module 120 configured to transfer wafers between the process tool and the input and output load ports 102, 104, 106, 108. The track-in module 120 may include a robot (not shown) or other suitable device to carry out the transfer.

In operation, a first lot of wafers may be housed in a load-in container such as the first FOUP 110, the first lot of wafers being ready for processing. The number of wafers in the first lot may vary depending on whether the wafers are for mass production, or for test runs by research/development (R/D), or for a combination thereof. Generally, the FOUP may house a maximum of twenty-five (25) wafers. The first FOUP 110 may be transported and placed in the first input load port 102 by an overhead transport (OHT) service 122 running throughout the fab. Also, a second lot of wafers may be housed in another load-in container such as the second FOUP 112, the second lot of wafers being ready for processing, and may be transported and placed in the second input load port 104 via the OHT service 122. It is understood that a surface of each wafer has been prepared according to a particular recipe with a photosensitive layer (e.g., photoresist or resist).

A load-out container such as the third FOUP 114 may be transported and placed in the first output load port 106 via the OHT service 122. The third FOUP 114 may be empty and available to be loaded with wafers after they have been processed by the process tool. Also, another load-out container such as the fourth FOUP 116 may be transported and placed in the second output load port 108 via the OHT service 122. The fourth FOUP 116 may be empty and available to be loaded with wafers after they have been processed by the process tool.

The robot may begin to transfer the first lot of wafers housed in the first FOUP 110 to a buffer of the lithography tool 118 for an exposure process via the track-in module 120. Once the entire first lot of wafers has been transferred to the buffer, the first FOUP 110 may be immediately removed 124 from the first input port 102 via the OHT service 122. A next lot of wafers housed in a next FOUP 130 may be transported and placed in the first input load port 102 via the OHT service 122.

After each of the first lot of wafers has been processed by the lithography tool 118, the processed wafer may be transferred to the third FOUP 114 positioned in the first output load port 106 via the track-in module 120. The third FOUP 114 may be loaded with the entire first lot of processed wafers. If the third FOUP 114 cannot be further loaded with a next lot of processed wafers, the third FOUP 114 is removed from the first output load port 106 and transported to a next station via the OHT service 122 for further processing such as post-exposure bake, development, hard bake, and inspection. After removal of the third FOUP 114, a next empty FOUP 132 may be transported and placed in the first output load port 106 which is available to be loaded with processed wafers. If the third FOUP 114 can be further loaded with a next lot of processed wafers, the third FOUP 114 remains in the first output load port 106.

After processing the first lot of wafers, the robot may begin transferring the second lot of wafers housed in the second FOUP 112 to the buffer of the lithography tool 118 for the exposure process via the track-in module 120. Once the entire second lot of wafers has been transferred to the buffer, the second FOUP 112 may be immediately removed 124 from the second input port 104 via the OHT service 122. A next lot of wafers housed in a next FOUP 134 may be transported and placed in the second input load port 104 via the OHT service 122.

After each of the second lot of wafers has been processed by the lithography tool 118, the processed wafer may be transferred to the third FOUP 114 in the first output load port 106 if the third FOUP is available for further loading, or to the fourth FOUP 116 positioned in the second output load port 108 via the track-in module 120 if the third FOUP 114 is not available for loading in the second lot. The fourth FOUP 116 may be loaded with the entire second lot of processed wafers. If the fourth FOUP 116 cannot be further loaded with a next lot of processed wafers, the fourth FOUP is removed from the second output load port 108 and transported to a next station via the OHT service 122 for further processing such as a post-exposure bake, development, hard bake, and inspection. After removal of the fourth FOUP 116, a next empty FOUP 136 may be transported and placed in the second output load port 108 which is available to be loaded with processed wafers. If the fourth FOUP 116 can be further loaded with a next lot of processed wafers, the fourth FOUP 116 remains in the second output load port 108.

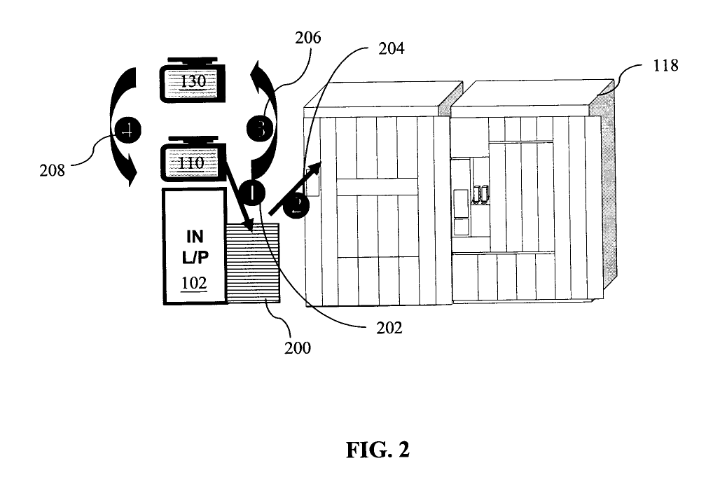

Referring now to FIG. 2, illustrated is a schematic diagram of a buffer 200 that may be utilized in the load port design of FIG. 1. Similar features in FIGS. 1 and 2 are numbered the same for clarity and simplicity. The buffer 200 may be configured to hold or store wafers that are waiting for processing by the lithography tool 118. The buffer 200 may be integral with the input load port 102. Alternatively, the buffer 200 may optionally have a separate structure that may be coupled to the input load port 102. It is understood that although only one input load port is shown with the buffer, a second input load port (in FIG. 1) may share the same buffer or have its own buffer configuration.

In operation, a lot of wafers ready for processing may be housed in a FOUP 110. The FOUP 110 may be transported and placed in the input load port 102 by an OHT service. The lot of wafers may be transferred 202 (Step 1) from the FOUP 110 to the buffer 200 by a robot coupled to a track module (not shown). Each wafer may then be transferred 204 (Step 2) to the lithography tool 118 for an exposure process. Once the entire lot of wafers has been transferred to the buffer 200, the FOUP 110 may be immediately removed 206 (Step 3) from the input load port 102 via the OHT service. After removal of the FOUP 110, a next FOUP 130 housing a next lot of wafers ready for processing may be transported and placed 208 (Step 4) in the input load port 102. In this way, a FOUP housing a lot of wafers may always be available in the input load port for processing. Accordingly, a continuous supply of wafers can be fed to the lithography tool even as wafer throughput increases with emerging technology. This reduces the idle or waiting time of the lithography tool and therefore, reduces the cost of ownership for the fab.

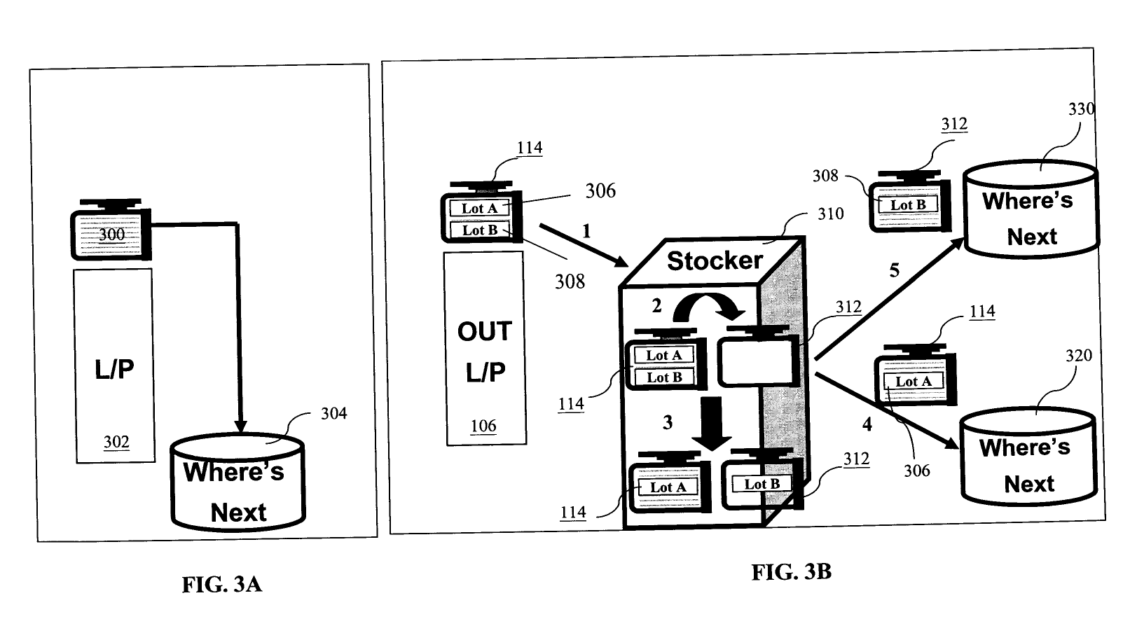

Referring now to FIGS. 3A and 3B, illustrated are schematic diagrams of a conventional load port design (FIG. 3A) and a shuttle bus design (FIG. 3B) that may be utilized with the load port design of FIG. 1. In FIG. 3A, a lot of wafers may be housed in a FOUP 300 ready for processing. As previously discussed, the FOUP 300 may be transported and placed in a load port 302 that interfaces with a processing tool. The lid of the FOUP 300 may be opened and the wafers fed into the processing tool via the load port. However, the FOUP 300 sits and waits in the load port 302 until all wafers in that particular lot have been processed and fed back out to the FOUP. The FOUP 300 housing the lot of processed wafers may then be transported to a next station 304 for further processing via an OHT service. Also, the FOUP 300 may typically house and transport a single lot of wafers with all the wafers being processed in the same manner.

In FIG. 3B, a shuttle bus design may be utilized with the load port design of FIG. 1. Similar features in FIGS. 1 and 3B are numbered the same for clarity and simplicity. The shuttle bus design may comprise an output load port 106 similar to the one described in FIG. 1. An empty FOUP 114 may be transported and placed in the output load port 106, via an OHT service, to be loaded with a lot of processed wafers from a processing tool. The number of wafers in the lot may vary depending a specific requirement of the fab (e.g., mass production, R/D, mixed run) and/or a particular recipe being followed. In the present example, the FOUP 114 may be loaded with a lot of ten (10) processed wafers referred to as Lot A 306. As previously discussed, a maximum number of twenty-five (25) wafers may be loaded in the FOUP 114. Accordingly, the FOUP 114 may not be fully utilized to its capacity. Accordingly, the FOUP 114 may additionally be loaded with a lot of twelve (12) processed wafers referred to as Lot B 308.

The shuttle bus design may record an identification number (ID) of Lot A 306 and Lot B 308 loaded in the FOUP 114 for tracking and logging information with an automated handling system of the fab. At the next location, the FOUP 114 may be placed in a load port of a stocker 310 via the OHT service (Step 1). The stocker 310 may be configured to store wafers, FOUPs and/or reticles waiting to be processed by another station and/or transported to another location. The stocker 310 may have a FOUP 312 available for loading in wafers to be transported to another location. Since the fab handling system is aware that Lot A 306 and Lot B 308 are both housed in the FOUP 114, a robot may be directed to only transfer Lot B 308 to the available FOUP 312 in the stocker 310 (Steps 2 and 3). The FOUP 114 may be transported to another location 320 where the wafers of Lot A 306 are scheduled to be processed (Step 4). The FOUP 312 may be transported to another location 330 where the wafers of Lot B 308 are scheduled to be processed (Step 5).

It is understood that the above is a mere example and that other scenarios may be implemented by the shuttle bus design. For example, the shuttle bus design may automatically merge two different lot of wafers that may be scheduled to be processed at the same location and with the same or different recipe. The shuttle bus design fully utilizes the capacity of the FOUP by allowing two or more lots of wafers to be housed therein and transported to various stations throughout the fab. Additionally, the shuttle bus design implements the output load port feature of FIG. 1 as a “shuttle bus station” where an empty FOUP is not removed from the output load port until is substantially loaded with processed wafers to be transported or “shuttled” to the various stations.

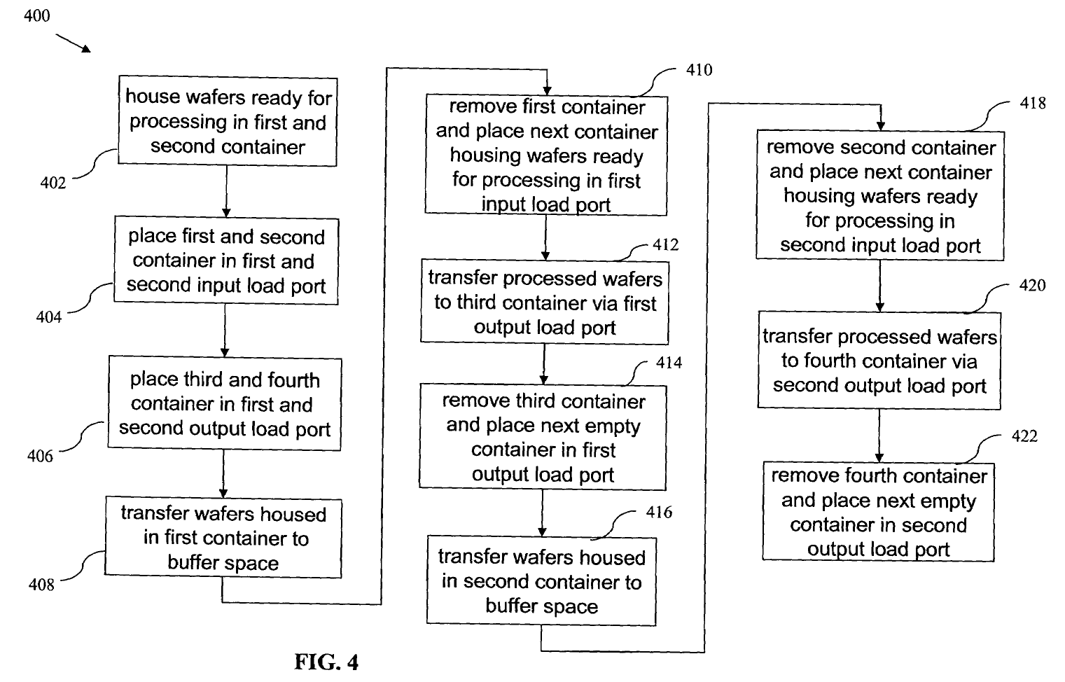

Referring now to FIG. 4, illustrated is a flow chart of a method 400 for supplying wafers to a processing tool utilizing the various aspects of the load port design of FIGS. 1 through 3. The method 400 begins with step 402 in which a plurality of wafers ready for processing may be housed in a first and second container. The first and second container may include a Front Opening Unified Pod (FOUP). The first container may house a first lot of wafers for processing with a first recipe and the second container may house a second lot of wafers for processing with a second recipe. It is understood that the number of wafers in each lot may vary and that the first and second recipes may be different or the same. The method 400 continues with step 404 in which the first and second containers may be transported and placed in a first and second input load port, respectively. The first and second containers may be transported by an overhead transport (OHT) service. The first and second input load ports may be configured to only feed in wafers to a processing tool such as a lithography tool.

The method 400 continues with step 406 in which a third and fourth container may be placed in a first and second output load port. The third and fourth containers may include a FOUP and, may be empty and available to be loaded with processed wafers. The first and second output load ports may be configured to only feed out processed wafers from the processing tool. The method 400 continues with step 408 in which the first lot of wafers housed in the first container may be transferred to a buffer of the processing tool via the first input load port. The buffer may be configured to hold or store wafers waiting to be processed by the processing tool. Alternatively, the input load port may optionally be configured to include a buffer for holding wafers waiting to be processed as was described in FIG. 2.

Once the entire first lot of wafers has been transferred to the buffer, the method 400 continues with step 410 in which the first container may be removed from the first input load port by the OHT service. Also, a next container housing a next lot of wafers ready for processing may be transported and placed in the first input load port by the OHT service. The method 400 continues with step 412 in which the first lot of processed wafers may be transferred from the processing tool to the third container via the first output port.

The method 400 continues with step 414 in which the third container may be removed from the first output load port and transported to a next station for further processing via the OHT service. Alternatively, the third container may optionally be loaded with another lot of processed wafers and may be used as a “shuttle bus” as was described in FIG. 3B. Additionally, a next empty container that is available to be loaded with processed wafers may be placed in the first output port. The method 400 continues with step 416 in which the second lot of wafers housed in the second container may be transferred to the buffer of the processing tool. Alternatively, the input load port may optionally be configured to include a buffer for holding wafers waiting to be processed as was described in FIG. 2.

Once the entire second lot of wafers has been transferred to the buffer, the method 400 continues with step 418 in which the second container may be immediately removed from the second input load port by the OHT service. Also, a next container housing a next lot of wafers ready for processing may be transported and placed in the second input load port by the OHT service. The method 400 continues with step 420 in which the second lot of processed wafers may be transferred to the fourth container via the second output load port if there no available container is present in the first output load port.

The method 400 continues with step 422 in which the fourth container may be removed from the second output load port and transported to a next station for further processing by the OHT service. Alternatively, the fourth container may optionally be loaded with another lot of processed wafers and may be used as a “shuttle bus” as was described in FIG. 3B. Also, a next empty container that is available to be loaded with processed wafers may be placed in the second output load port. It is understood that various different combinations of the above listed processing steps can be implemented in combination or in parallel.

Thus, provided is a system for use in semiconductor manufacturing including a process tool for processing the wafers, a buffer coupled to the process tool for holding wafers waiting to be processed by the process tool; an input load port coupled to the buffer for feeding in wafers ready for processing from a load-in container; an output load port coupled to the process tool for feeding out wafers that have been processed by the process tool to a load-out container; and a track module for transporting the wafers the buffer, the process tool, and the input and output load ports. In some embodiments, the load-in and load-out containers include front opening unified pods (FOUP). In some other embodiments, the system further includes an overhead transport (OHT) service for transporting the plurality of FOUP to and from the input and output load ports.

In other embodiments, the system further includes a track robot coupled to the track module for transporting the wafers between the various components. In some other embodiments, the output load port is configured as a shuttle bus station. In other embodiments, the load-out container is adapted for housing processed wafers from different lots that have been processed by the process tool. In some other embodiments, the system further includes a stocker for receiving the load-out container. In still other embodiments, the process tool includes a lithography tool.

Also provided is a method for use in semiconductor manufacture including the steps of housing a first lot of wafers in a load-in container; transferring the first lot of wafers from the load-in container to a buffer; processing the first lot of wafers in the buffer; and transferring the first lot of processed wafers to a load-out container. In other embodiments, the method further includes the step of immediately removing the load-in container once the entire first lot of wafers has been transferred to the buffer. The load-in container is disposed in an input load port and the load-out container is disposed in an output load port. In some embodiments, the method further includes the step of: housing a second lot of wafers in another load-in container; transferring the second lot of wafers from the another load-in container to the buffer; and processing the second lot of wafers in the buffer. The another load-in container is disposed in the input load port.

In some other embodiments, the method further includes the step of immediately removing the another load-in container from the input load port once the entire second lot of wafers has been transferred to the buffer. In still other embodiments, the method further includes the steps of: transferring the second lot of processed wafers to the load-out container; transporting the load-out container from the output load port to another location; and providing another empty load-out container into the output load port. In still other embodiments, the method further includes the steps of: transporting the load-out container from the output load port to another location; providing another empty load-out container into the output load port; and transferring the second lot of processed wafers to the another load-out container. In other embodiments, the step of processing the first lot of wafer includes processing the first lot of wafers with a lithography tool and the step of processing the second lot of wafer includes processing the second lot of wafers with the lithography tool

Additionally, an apparatus for use in semiconductor manufacture is provided including a first input load port for receiving a first load-in container that houses a first lot of wafers ready for processing; a first output load port for receiving a first load-out container adapted to be loaded with wafers that have been processed; and a buffer coupled to the first input load port for storing the first lot of wafers ready for processing. In some embodiments, the apparatus further includes a second input load port for receiving a second load-in container that houses a second lot of wafers ready for processing; and a second output load port for receiving a second load-out container adapted to be loaded with wafers that have been processed. The buffer is coupled to the second input load port for storing the second lot of wafers ready for processing. In some other embodiments, the load-in and load-out containers include front opening unified pods (FOUP). In some other embodiments, the first load-out container includes processed wafers from the first lot and the second load-out container includes processed wafers from the second lot. In other embodiments, the first load-out container includes processed wafers form the first and second lots.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. For example, the buffer for storing unprocessed wafers may be an integral part of the processing tool or may be a separate structure coupled with the processing tool. Those skilled in the art should also realize that such equivalent constructions do not depart from the spirit and scope of the present disclosure, and that they may make various changes, substitutions and alterations herein without departing from the spirit and scope of the present disclosure.

Several different advantages exist with these and other embodiments. In addition to providing a simple and cost-effective system and method for supplying wafers to an in-line lithography tool, the system and method can be easily integrated with current semiconductor processing equipment and techniques. Also, the system and method disclosed herein can be utilized even as lithography tools increase wafer throughput. Furthermore, the system and method disclosed herein does not require additional foot in the fab and eliminates the need for manually merging small lot sizes.

What is claimed is:

1. A system for use in semiconductor manufacturing, the system comprising:
a process tool for processing wafers;
a buffer coupled to the process tool for holding wafers waiting to be processed by the process tool;
an input load port coupled to the buffer for feeding in wafers ready for processing from a load-in container;
an output load port coupled to the process tool for feeding out wafers that have been processed by the process tool to a load-out container; and
a track module for transporting wafers between the buffer, the process tool, and the input and output load ports.

2. The system of claim 1, wherein the load-in and load-out containers include front opening unified pods (FOUP).

3. The system of claim 2, further comprising an overhead transport (OHT) service for transporting the FOUP to and from the input load port, and to and from the output load port.

4. The system of claim 1, further comprising a track robot coupled to the track module for transporting the wafers between the various components.

5. The system of claim 1, wherein the output load port is configured as a shuttle bus station.

6. The system of claim 5, wherein the load-out container is adapted for housing wafers form different lots that have been processed by the process tool.

7. The system of claim 6, further comprising a stocker for receiving the load-out container.

8. The system of claim 1, wherein the process tool includes a lithography tool.

9. A method for use in semiconductor manufacture, the method comprising:
housing a first lot of wafers ready for processing in a load-in container;
transferring the first lot of wafers from the load-in container to a buffer;
processing the first lot of wafers in the buffer; and
transferring the first lot of processed wafers to a load-out container.

10. The method of claim 9, further comprising immediately removing the load-in container once the entire first lot of wafers has been transferred to the buffer, wherein the load-in container is disposed in an input load port and the load-out container is disposed in an output load port.

11. The method of claim 10, further comprising:
housing a second lot of wafers ready for processing in another load-in container;
transferring the second lot of wafers from the another load-in container to the buffer; and
processing the second lot of wafers in the buffer;
wherein the another load-in container is disposed in the input load port.

12. The method of claim 11, further comprising immediately removing the another load-in container from the input load port once the entire second lot of wafers has been transferred to the buffer.

13. The method of claim 12, further comprising:
transferring the second lot of processed wafers to the load-out container;
transporting the load-out container from the output load port to another location; and
providing another empty load-out container into the output load port.

14. The method of claim 12, further comprising:
transporting the load-out container from the output load port to another location;
providing another empty load-out container into the output load port; and
transferring the second lot of processed wafers to the another load-out container.

15. The method of claim 10, wherein the processing the first lot of wafers includes processing the first lot of wafers with a lithography tool and wherein the processing the second lot of wafers includes processing the second lot of wafers with the lithography tool.

16. An apparatus for use in semiconductor manufacture, comprising:
a first input load port for receiving a first load-in container that houses a first lot of wafers ready for processing;
a first output load port for receiving a first load-out container adapted to be loaded with wafers that have been processed; and
a buffer coupled to the first input load port for storing the first lot of wafers ready for processing.

17. The apparatus of claim 16, further comprising:
a second input load port for receiving a second load-in container that houses a second lot of wafers ready for processing; and
a second output load port for receiving a second load-out container adapted to be loaded with wafers that have been processed;
wherein the buffer is coupled to the second input load port for storing the second lot of wafers ready for processing.

18. The apparatus of claim 17, wherein the load-in and load-out containers include front opening unified pods (FOUP).

19. The apparatus of claim 17, wherein the first load-out container includes processed wafers from the first lot and the second load-out container includes processed wafers from the second lot.

20. The apparatus of claim 17, wherein the first load-out container includes processed wafers from the first and second lots.
